(19) United States
(12) Patent Application Publication
(10) Pub. No.: US 2026/0101717 A1
(43) Pub. Date: Apr. 9, 2026

(54) SUBSTRATE TRANSPORT ROBOT SYSTEM

(71) Applicant: KAWASAKI JUKOGYO KABUSHIKI KAISHA, Kobe-shi, Hyogo (JP)

(72) Inventors: Hiroki IMANISHI, Kobe-shi (JP); Shinya KITANO, Kobe-shi (JP); Atsushi NAKAYA, Kobe-shi (JP)

(73) Assignee: KAWASAKI JUKOGYO KABUSHIKI KAISHA, Kobe-shi, Hyogo (JP)

(21) Appl. No.: 19/115,030

(22) PCT Filed: Oct. 12, 2023
(86) PCT No.: PCT/JP2023/037070

§ 371 Date: Mar. 25, 2025

(30) Foreign Application Priority Data
Oct. 14, 2022 (JP) 2022-165450

(51) Int. Cl. H10P 72/76; B25J 9/16; B25J 11/00; B25J 15/00; H10P 72/00

(52) U.S. Cl. CPC H10P 72/7602; B25J 9/1694; B25J 11/0095; B25J 15/0014; H10P 72/0606

(57) ABSTRACT

A substrate transport robot system includes a substrate holding hand to hold a plurality of substrates, a robot arm, and a controller. The controller is configured or programmed to acquire an amount of deviation of placement of each of the plurality of substrates with respect to a predetermined reference position based on a detection result of a detector, and control a transport operation of the robot arm operable to transport the plurality of substrates based on an acquired amount of deviation such that each of the plurality of substrates is loaded separately into a mount and/or unloaded separately from the mount.

### TECHNICAL FIELD

The present disclosure relates to a substrate transport robot system, and more particularly, it relates to a substrate transport robot system including a substrate holding hand that holds a plurality of substrates.

### BACKGROUND ART

Conventionally, a substrate transport robot system that holds a plurality of substrates is known. For example, Japanese Patent No. 6833685 discloses a substrate processing apparatus including a transfer robot to transport a substrate. An end effector that holds the substrate is arranged on an arm of the transfer robot. The substrate processing apparatus disclosed in Japanese Patent No. 6833685 includes a reference surface arranged in a predetermined positional relationship with respect to a substrate holding position to which the substrate is to be transported. The substrate processing apparatus brings the substrate held by the end effector into contact with the reference surface to move the substrate on the end effector to change the eccentricity between the end effector and the substrate. Then, by measuring the change in the eccentricity between the end effector and the substrate, the substrate holding position is taught to the transfer robot based on the measured change in the eccentricity and the positional relationship between the substrate holding position and the reference surface. Japanese Patent No. 6833685 also discloses an example of the substrate processing apparatus in which the substrate on the end effector is brought into contact with a predetermined contact surface or pin, for example, to deviate the substrate to a predetermined position with respect to the end effector. Japanese Patent No. 6833685 also discloses an example in which the end effector that holds two substrates side by side is arranged on one arm such that the transfer robot transports two substrates together.

### PRIOR ART

### Patent Document

Patent Document 1: Japanese Patent No. 6833685

### SUMMARY OF THE INVENTION

Although not clearly described in Japanese Patent No. 6833685, when a substrate is transported as in the case of the transport robot of the substrate processing apparatus described in Japanese Patent No. 6833685, the position of the substrate held by a hand, which is an end effector, may deviate on the hand. For example, when a substrate is held for transportation, the substrate may be held in a state in which it is deviated from a predetermined position with respect to the hand. In particular, when a plurality of substrates are transported together, the amount of positional deviation on the hand may differ between the plurality of substrates. In such a case, when each of the plurality of substrates on the hand is moved by bringing the substrate into contact with a predetermined contact surface or a member other than the substrate, such as a pin, as in Japanese Patent No. 6833685, the contact may conceivably cause abnormalities such as cracks or deformation in the substrate, or foreign matter generated by the contact may conceivably cause abnormalities in the processing of the substrate. Furthermore, when contact between the substrate and the member other than the substrate is reduced or prevented, the substrate is transported while being deviated on the hand, and thus it is difficult to accurately transport each of the plurality of substrates to its destination mount. Therefore, it is difficult to accurately transport the plurality of substrates while reducing or preventing contact with the member other than the substrates.

The present disclosure is intended to solve the above problems. The present disclosure aims to provide a substrate transport robot system capable of accurately transporting a plurality of substrates while reducing or preventing contact with a member other than the substrates.

A substrate transport robot system according to an aspect of the present disclosure includes a substrate holding hand including a plurality of holders to hold a plurality of substrates, respectively, a robot arm including the substrate holding hand attached thereto, and a controller configured or programmed to acquire an amount of deviation of placement of each of the plurality of substrates with respect to a predetermined reference position based on a detection result of a detector operable to detect each of the plurality of substrates held by the substrate holding hand, and control a transport operation of the robot arm operable to transport the plurality of substrates based on an acquired amount of deviation such that each of the plurality of substrates is loaded separately into a mount and/or unloaded separately from the mount.

As described above, the substrate transport robot system according to the aspect of the present disclosure includes the controller configured or programmed to acquire the amount of deviation of the placement of each of the plurality of substrates with respect to the predetermined reference position based on the detection result of the detector operable to detect each of the plurality of substrates held by the substrate holding hand, and control the transport operation of the robot arm operable to transport the plurality of substrates based on the acquired amount of deviation such that each of the plurality of substrates is loaded separately into each of the mount and/or unloaded separately from the mount. Accordingly, even when the substrates are deviated from the predetermined reference position, the controller controls the transport operation of the robot arm based on the amount of deviation such that each of the plurality of substrates can be transported so as to correct the placement deviation without changing the relative placement of each of the plurality of substrates with respect to the substrate holding hand. Consequently, the plurality of substrates can be accurately transported while contact with a member other than the substrates is reduced or prevented.

According to the present disclosure, it is possible to accurately transport the plurality of substrates while reducing or preventing contact with the member other than the substrates.

### BRIEF DESCRIPTION OF THE DRAWINGS

FIG. 1 is a schematic view showing the overall configuration of a substrate processing system including a substrate transport robot system according to an embodiment.

FIG. 2 is a block diagram showing the configuration of the substrate processing system including the substrate transport robot system.

FIG. 3 is a perspective view schematically showing the substrate transport robot system.

FIG. 4 is a diagram for illustrating the configuration of a mount in a load lock.

FIG. 5 is a diagram for illustrating the configuration of a mount in each of a plurality of processing modules.

FIG. 6 is a diagram for illustrating detection of substrates in detectors.

FIG. 7 is a diagram for illustrating the operation to transport substrates to the mount of each of the plurality of processing modules.

FIG. 8 is a diagram for illustrating the operation to transport substrates to the mount of the load lock.

FIG. 9 is a flowchart for illustrating a control process of a substrate transport method by the substrate transport robot system.

FIG. 10 is a schematic view for illustrating processing modules according to a modified example of the embodiment of the present disclosure.

### MODES FOR CARRYING OUT THE INVENTION

An embodiment embodying the present disclosure is hereinafter described on the basis of the drawings.

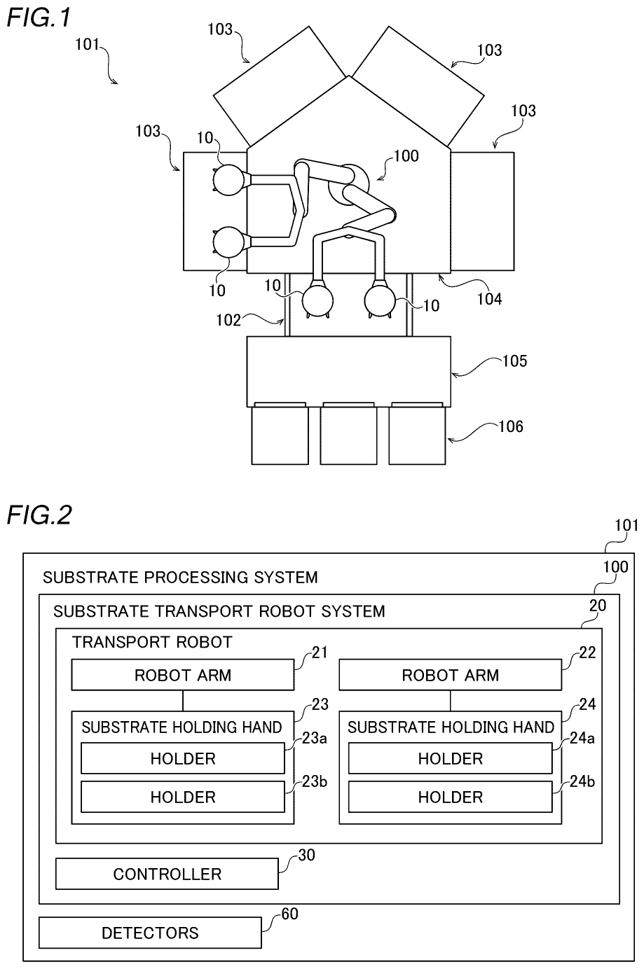

The configuration of a substrate transport robot system 100 according to the embodiment is now described with reference to FIGS. 1 to 8.

### Configuration of Substrate Processing System

As shown in FIG. 1, the substrate transport robot system 100 according to this embodiment transports substrates 10 in a substrate processing system 101. The substrate processing system 101 includes the substrate transport robot system 100, a load lock 102, and a plurality of processing modules 103. In an example of FIG. 1, the substrate processing system 101 includes four processing modules 103. The substrate processing system 101 also includes a transport chamber 104 and a loading/unloading chamber 105. The substrate processing system 101 performs a process on the substrates 10 such as semiconductor wafers or printed circuit boards. The substrates 10 are, for example, glass substrates or silicon substrates having a substantially disk shape.

Each of the processing modules 103 performs a process such as resist coating or etching on the substrates 10. The plurality of processing modules 103 are arranged along the outer periphery of the transport chamber 104. The inside of the transport chamber 104 is maintained at a predetermined vacuum level. In other words, the substrate processing system 101 is a multi-chamber type vacuum processing apparatus. The load lock 102 is provided on the outer periphery of the transport chamber 104. The loading/unloading chamber 105 is provided on the opposite side of the load lock 102 to the transport chamber 104. Three ports are provided on the opposite side of the loading/unloading chamber 105 to the load lock 102 to attach carriers 106 capable of accommodating the substrates 10.

The substrate transport robot system 100 unloads the substrates 10 from the processing modules 103 in which the process is performed on the substrates 10, and loads the substrates 10 into the processing modules 103. In the substrate processing system 101, a transport robot (not shown) arranged in the loading/unloading chamber 105 loads the substrates 10 from the carriers 106 into the load lock 102. Then, the substrate transport robot system 100 according to this embodiment transports the substrates 10 from the load lock 102 to each of the plurality of processing modules 103. The substrates 10 that have been processed in each of the plurality of processing modules 103 are transported from each of the plurality of processing modules 103 to the load lock 102 by the substrate transport robot system 100. The processed substrates 10 are then unloaded from the load lock 102 to the carriers 106 by the transport robot (not shown) arranged in the loading/unloading chamber 105. The carriers 106 store a plurality of substrates 10.

### Configuration of Substrate Transport Robot System

As shown in FIG. 2, the substrate transport robot system 100 includes a transport robot 20 and a controller 30. The transport robot 20 includes a robot arm 21 and a robot arm 22. A substrate holding hand 23 and a substrate holding hand 24 are attached to the robot arm 21 and the robot arm 22, respectively. The transport robot 20 is arranged substantially in the center of the transport chamber 104. The robot arm 21 and the robot arm 22 are examples of a first robot arm and a second robot arm, respectively.

The controller 30 is a computer including a central processing unit (CPU), a random access memory (RAM), and a read-only memory (ROM), for example. The controller 30 also includes a storage including a flash memory such as a solid state drive (SSD). The controller 30 may be spaced apart from the transport robot 20, or may be arranged integrally with the transport robot 20. The controller 30 controls the operation of each portion of the substrate transport robot system 100 based on a program and parameters stored in the storage in advance. In this embodiment, the controller 30 controls the transport operation of each of the robot arms 21 and 22 that transport a plurality of substrates 10. The controller 30 controls the operation to transport the substrates 10 based on control signals from a higher-level control device (not shown) that controls the entire substrate processing system 101. The control of the transport operation by the controller 30 is described below in detail.

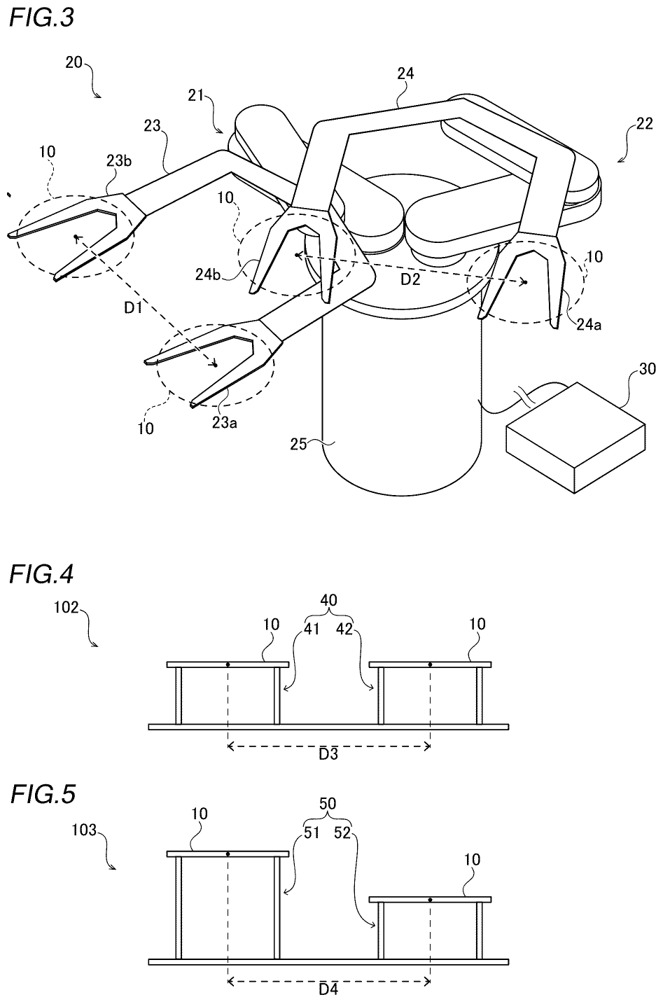

As shown in FIG. 3, the transport robot 20 is a horizontal articulated wafer transport robot that loads and unloads the substrates 10 between the load lock 102 and the processing modules 103. Each of the robot arms 21 and 22 rotates, expands, and contracts by driving a plurality of joints. Each of the robot arms 21 and 22 operates separately by a control process of the controller 30. Specifically, each of the robot arms 21 and 22 includes two arms connected to each other. Each of the robot arms 21 and 22 includes a servomotor as a drive source. Each of the robot arms 21 and 22 also includes an encoder that acquires the number of rotations of the Servomotor. The controller 30 controls the operation of each of the robot arms 21 and 22 by a feedback control based on an output from the encoder. The robot arms 21 and 22 include, respectively, the substrate holding hand 23 and the substrate holding hand 24 attached to first ends of the two mutually connected arms, and are connected to a common base 25 at second ends of the two mutually connected arms. Each of the robot arms 21 and 22 rotates, expands, and contracts separately with respect to the base 25. The base 25 includes a linear motion mechanism that moves each of the robot arms 21 and 22 separately in a vertical direction. This linear motion mechanism includes a servomotor as a drive source, for example.

Each of the substrate holding hands 23 and 24 holds a pair of substrates 10. Specifically, the substrate holding hand 23 includes a pair of holders 23a and 23b. Similarly, the substrate holding hand 24 includes a pair of holders 24a and 24b. The holders 23a and 23b hold the pair of substrates 10, respectively. That is, each of the holders 23a and 23b holds one substrate 10. Similarly, each of the holders 24a and 24b holds one substrate 10. Each of the holders 23a, 23b, 24a, and 24b is a thin support plate that supports the substrate 10. Each of the holders 23a, 23b, 24a, and 24b has a U-shape with a bifurcated distal end, and supports the rear surface of the outer periphery of the substantially disk-shaped substrate 10 from below in the vertical direction. The substrate holding hands 23 and 24 do not include actuators or the like that drive the holders 23a, 23b, 24a, and 24b to fix the substrates 10 held by the holders 23a, 23b, 24a, and 24b, and are passive-type end effectors that support the substrates 10 from below in the vertical direction without fixing the substrates 10.

In each of the substrate holding hands 23 and 24, the pair of substrates 10 are held while being aligned right and left along a horizontal plane. The holder 23a and the holder 23b, and the holder 24a and the holder 24b are integral and unitary with each other. That is, in each of the substrate holding hands 23 and 24, the pair of substrates 10 are held in a state in which the relative positional relationship is fixed. The substrate transport robot system 100 transports the pair of substrates 10 held by the substrate holding hand 23 integrally by operating the robot arm 21. Similarly, the substrate transport robot system 100 transports the pair of substrates 10 held by the substrate holding hand 24 integrally by operating the robot arm 22. The configuration of the substrate holding hand 23 and the configuration of the substrate holding hand 24 are common to each other. In other words, a distance D1 between the centers of positions at which the substrates 10 are held by the holders 23a and 23b of the substrate holding hand 23 and a distance D2 between the centers of positions at which the substrates 10 are held by the holders 24a and 24b of the substrate holding hand 24 are substantially equal to each other such that a distance between the pair of substrates 10 held by the substrate holding hand 23 and a distance between the pair of substrates 10 held by the substrate holding hand 24 are substantially equal to each other.

As shown in FIG. 4, in the load lock 102, the substrates 10 are placed on mounts 40. The mounts 40 include a pair of mounts 41 and 42 that are substantially equal in height, which is a vertical position at the placement position. Each of the substrate holding hands 23 and 24 collectively holds the substrates 10 placed on the mounts 41 and 42. In the load lock 102, a distance D3 between the centers of positions at which the substrates 10 are held on the mounts 41 and 42 is substantially equal to each of the distance D1 between the holders 23a and 23b and the distance D2 between the holders 24a and 24b.

As shown in FIG. 5, each of the plurality of processing modules 103 includes mounts 50 on which the substrates 10 are to be placed. For example, each of the plurality of processing modules 103 processes two substrates 10 at a time. That is, in each of the processing modules 103, two substrates 10 are placed on the mounts 50. Specifically, each of the processing modules 103 includes, as the mounts 50, a pair of mounts 51 and 52 having different placement position heights. The pair of mounts 51 and 52 are different in height, which is a vertical position at the placement position. Specifically, the placement position height of the mount 52 is lower than that of the mount 51. Furthermore, the positional relationship in a horizontal direction is similar to that between the mounts 41 and 42. That is, in a plan view, the mounts 51 and 52 are arranged with the centers of the positions at which the substrates 10 are held spaced apart by a distance D4, which is substantially equal to the distance D1 between the holders 23a and 23b and the distance D2 between the holders 24a and 24b, similarly to the mounts 41 and 42. Therefore, the distance D4 in each of the plurality of processing modules 103 is substantially equal to the distance D3 in the load lock 102.

The substrate transport robot system 100 transports a pair of substrates 10 together between the load lock 102 and each of the plurality of processing modules 103 by operating the two robot arms 21 and 22 separately. That is, in the substrate transport robot system 100, a pair of substrates 10 are transported together between the two mounts 41 and 42 of the load lock 102 and the two mounts 51 and 52 of each of the processing modules 103.

### Detector

As shown in FIG. 2, the substrate processing system 101 includes detectors 60. The detectors 60 detects the pair of substrates 10 held by each of the substrate holding hands 23 and 24 of the transport robot 20. The detectors 60 detect the pair of substrates 10 for each of the robot arms 21 and 22.

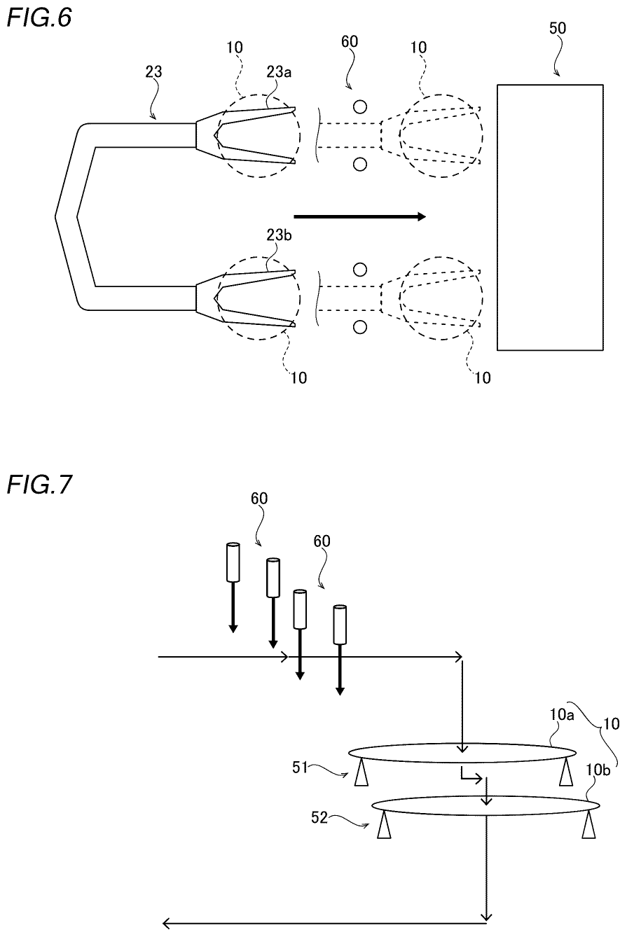

As shown in FIG. 6, specifically, the detectors 60 include a plurality of transmissive laser sensors. The detectors 60 include, as the transmissive laser sensors, light emitters including light sources such as light-emitting diodes (LEDs) that emit laser light, and light receivers including light-receiving elements such as charge coupled device (CCD) image sensors. For example, the detectors 60 are arranged on the load lock 102 side and on each side of the plurality of processing modules 103 in the transport chamber 104 of the substrate processing system 101. The detectors 60 are arranged such that positions through which the substrates 10 pass during the transport operation are detection target areas with respect to the mounts 40 or the mounts 50. That is, the detectors 60 are arranged so as to detect the positions through which the substrates 10 pass before the mounts 40 or the mounts 50 when the substrates 10 held by each of the substrate holding hands 23 and 24 are transported toward the mounts 40 or the mounts 50.

Four detectors 60 are arranged for each of the mounts 40 and 50 on which the pair of substrates 10 are to be placed. That is, a pair of detectors 60, which are transmissive laser sensors each including a pair of a light emitter and a light receiver, are arranged for each of the mounts 41 and 42 of the mounts 40 or for each of the mounts 51 and 52 of the mounts 50, on which one substrate 10 is to be placed. In the substrate processing system 101, one substrate 10 is detected by a pair of detectors 60. For example, in the example of FIG. 1, a pair of substrates 10 are transported to each of the four processing modules 103 and one load lock 102. Therefore, in the substrate processing system 101, four detectors 60 are arranged for each of the four processing modules 103 and one load lock 102, and a total of twenty detectors 60 are arranged. Each of a plurality of detectors 60 outputs a detection result indicating that the substrate 10 has been detected to the controller 30. Although FIG. 6 illustrates an example in which the substrates 10 are transported to the mounts 50 of the processing module 103 by the substrate holding hand 23, the same applies to transport by the substrate holding hand 24 and to transport to the mounts 40.

### Details of Control of Transport Operation by Controller

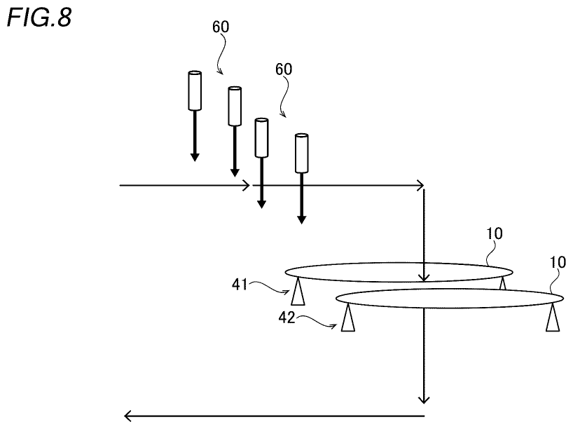

As shown in FIGS. 7 and 8, in this embodiment, the controller 30 controls the transport operations of the robot arm 21 and the robot arm 22 based on the detection results of the detectors 60 such that each of the pair of substrates 10 is loaded separately into the mounts 41 and 42 of the mounts 40 and the mounts 51 and 52 of the mounts 50. The control of the transport operation of the robot arm 21 and the control of the transport operation of the robot arm 22 are similar to each other, and thus in the following description, only the control of the transport operation of the robot arm 21 is described, and description of the control of the transport operation of the robot arm 22 is omitted.

In this embodiment, after each of the pair of substrates 10 is held by the substrate holding hand 23, the controller 30 acquires the amount of deviation of each of the pair of substrates 10 held by the substrate holding hand 23 with respect to a predetermined reference position based on the detection results of the detectors 60. For example, the controller 30 acquires the amount of deviation of the placement of each of the pair of substrates 10 with respect to the substrate holding hand 23 based on the detection results of the detectors 60. The acquired “amount of deviation” includes the magnitude and direction of the positional deviation with respect to the substrate holding hand 23 along the horizontal plane.

Specifically, the controller 30 calculates the positions of four points on the periphery of one substrate 10 based on the detection results from two detectors 60 in order to acquire the amount of deviation of one substrate 10 with respect to the substrate holding hand 23. For each of the detectors 60, which are transmissive laser sensors, two points are detected: a point at which the laser light is switched from a transmission state to a light blocking state due to the passage of the substrate 10, and a point at which the laser light is switched from the light blocking state to the transmission state. The controller 30 stores in advance the positions that are the detection targets of the detectors 60. The controller 30 acquires the positions of the four points on the periphery of the substrate 10 by acquiring the positions that are the detection targets of the detectors 60 and a speed at which the substrate holding hand 23 is moved. Then, the controller 30 calculates a circle that passes through three of the four acquired points as the substrate 10. There are four ways to select three points from the four points, and thus the controller 30 calculates four circles from the positions of the four acquired points. The controller 30 acquires the average position of the center points of these four circles as the center position of the substrate 10 held by the substrate holding hand 23. When any of the positions of the four points on the periphery of the substrate 10 is detected as being outside a predetermined range, it may be excluded as a notch or an orientation flat as a position reference, and the center of a circle passing through the remaining three points may be set as the center position of the substrate 10. The controller 30 may also determine whether or not an abnormality has occurred in the transport of the substrate 10 by determining whether or not the substrate 10 is placed at a position outside the predetermined range in the substrate holding hand 23.

In this manner, the controller 30 calculates the center position of each of the pair of substrates 10 held by the substrate holding hand 23. The controller 30 then stores in advance, as a reference arrangement position, the results detected by the detectors 60 when the substrates 10 are not positionally deviated in the substrate holding hand 23. When transporting the pair of substrates 10, the controller 30 calculates the amount of deviation of each of the substrates 10 with respect to the substrate holding hand 23 by comparing the detection results of the detectors 60 with the reference arrangement position stored in advance.

In this embodiment, the controller 30 controls the transport operation of the robot arm 21 based on the amount of deviation of each of the pair of substrates 10 acquired after the pair of substrates 10 are held by the substrate holding hand 23 such that each of the pair of substrates 10 held by each of the pair of holders 23a and 23b in the substrate holding hand 23 is placed separately onto the mounts 40 or the mounts 50.

### When the Substrates are Placed Onto the Mount of the Processing Module

As shown in FIG. 7, when a pair of substrates 10 are loaded separately into a pair of mounts 51 and 52 having different placement position heights during the transport operation of the robot arm 21, the controller 30 sequentially places each of the pair of substrates 10 onto each of the pair of mounts 51 and 52 based on the acquired amount of deviation of each of the pair of substrates 10. For example, of the pair of substrates 10 held by the substrate holding hand 23, one substrate 10 held by the holder 23a and placed on the mount 51 having a relatively high placement position is defined as a substrate 10a. The other substrate 10 held by the holder 23b and placed on the mount 52 having a relatively low placement position is defined as a substrate 10b. The substrates 10a and 10b are examples of a first substrate and a second substrate, respectively.

The controller 30 acquires the amount of deviation of each of the substrates 10a and 10b based on the detection results of the detectors 60. Then, when each of the substrates 10a and 10b, which are a pair of substrates 10, is loaded separately into each of the mounts 51 and 52, the controller 30 controls the transport operation of the robot arm 21 based on the amount of deviation of the substrate 10a such that the substrate 10a is placed onto the mount 51. Then, the controller 30 controls the transport operation of the robot arm 21 based on the amount of deviation of the substrate 10b such that the substrate 10b is placed onto the mount 52 after the substrate 10a is placed on the mount 51.

For example, when the substrates 10a and 10b, which are a pair of substrates 10, are transported to the processing module 103, the controller 30 controls the transport operation of the robot arm 21 to move the substrate holding hand 23 holding the substrates 10a and 10b toward the mounts 51 and 52, which are the mounts 50 of the processing module 103. During this movement, the detectors 60 arranged on the processing module 103 side detect each of the substrates 10a and 10b, and the controller 30 acquires the amount of deviation of each of the substrates 10a and 10b based on the detection results of the detectors 60. The controller 30 operates the robot arm 21 such that the substrate 10a held by the holder 23a of the substrate holding hand 23 is arranged vertically directly above the position at which the substrate 10a is to be placed on the mount 51 while correcting the transport operation of the robot arm 21 based on the acquired amount of deviation of the substrate 10a with respect to the preset position of the mount 51. Then, the controller 30 lowers the robot arm 21 vertically downward such that the substrate 10a is placed on the mount 51.

After the substrate 10a is placed on the mount 51, the controller 30 operates the robot arm 21 based on the acquired amount of deviation of the substrate 10b such that the substrate 10b held by the holder 23b of the substrate holding hand 23 is arranged vertically directly above the position at which the substrate 10b is to be placed on the mount 52. At this time, the controller 30 moves the substrate holding hand 23 along the horizontal plane to adjust the position of the substrate 10b in the horizontal plane while the substrate 10b is held at a height position between the mounts 51 and 52 in the vertical direction. Then, the controller 30 lowers the robot arm 21 vertically downward such that the substrate 10b is placed on the mount 52. After the substrate 10b is placed on the mount 52, the controller 30 operates the robot arm 21 such that the substrate holding hand 23 moves away from the processing module 103.

### When the Substrates are Placed Onto the Mount of the Load Lock

As shown in FIG. 8, in this embodiment, when each of a pair of substrates 10 is loaded separately into each of a pair of mounts 41 and 42 having substantially equal placement position heights during the transport operation of the robot arm 21, the controller 30 places each of the pair of substrates 10 substantially simultaneously onto each of the pair of mounts 41 and 42 based on the amount of deviation of each of the pair of substrates 10. Specifically, the controller 30 controls the transport operation of the robot arm 21 based on the average value of the amounts of deviation of the pair of substrates 10 such that each of the pair of substrates 10 is placed substantially simultaneously onto each of the pair of mounts 41 and 42.

When a pair of substrates 10 are transported to the load lock 102, the controller 30 controls the transport operation of the robot arm 21 to move the substrate holding hand 23 holding the pair of substrates 10 toward the mounts 41 and 42, which are the mounts 40 of the load lock 102. As in a case in which the substrates 10 are transported to the processing module 103, the detectors 60 detect each of the pair of substrates 10 during this movement, and the controller 30 acquires the amount of deviation of each of the pair of substrates 10 based on the detection results of the detectors 60. Then, the controller 30 calculates the average value of the amounts of deviation of the pair of substrates 10, and corrects the transport operation of the robot arm 21 based on the calculated average value of the amounts of deviation. That is, the controller 30 operates the robot arm 21 such that the positions of both of the pair of substrates 10 held by the substrate holding hand 23 are corrected in the same direction by the magnitude of the average value of the amounts of deviation vertically above the mounts 41 and 42. Then, the controller 30 lowers the robot arm 21 vertically downward such that the pair of substrates 10 are placed substantially simultaneously onto the mounts 41 and 42. After the pair of substrates 10 are placed on the mounts 41 and 42, the controller 30 operates the robot arm 21 such that the substrate holding hand 23 moves away from the load lock 102.

The control of the transport operation of the robot arm 22 when a pair of substrates 10 held by the substrate holding hand 24 are transported is similar. The controller 30 acquires the amounts of deviation of the pair of substrates 10 for each of the robot arms 21 and 22 based on the detection results of the detectors 60. Furthermore, the controller 30 controls the transport operation of each of the robot arms 21 and 22 based on the amount of deviation of each of the pair of substrates 10 acquired for each of the robot arms 21 and 22 such that each of the pair of substrates 10 is placed separately onto each of the mounts 41 and 42 of the mounts 40, or each of the mounts 51 and 52 of the mounts 50. The controller 30 controls the transport operation of the robot arm 21 and the transport operation of the robot arm 22 such that they are alternately performed.

### Control Process of Substrate Transport Method

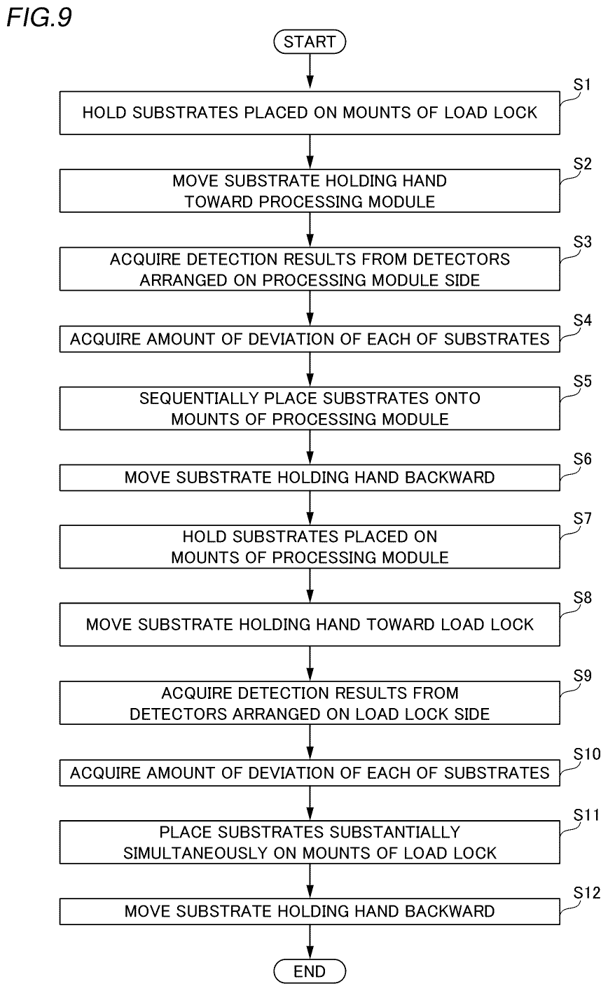

A control process of a substrate transport method by the substrate transport robot system 100 is now described with reference to FIG. 9. This control process of the substrate transport method is performed by the controller 30.

First, in step S1, the substrates 10 placed one by one on the mounts 41 and 42 of the load lock 102 are held by the holders 23a and 23b of the substrate holding hand 23, respectively.

Next, in step S2, the operation of the robot arm 21 is controlled to move the substrate holding hand 23 toward one of the plurality of processing modules 103.

Next, in step S3, the detectors 60 arranged on the processing module 103 side detect the pair of substrates 10 held by the holders 23a and 23b of the substrate holding hand 23, respectively, such that the detection results from the detectors 60 are acquired.

Next, in step S4, the amount of deviation of the placement of each of the pair of substrates 10 with respect to the substrate holding hand 23 is acquired based on the detection results acquired from the detectors 60.

Next, in step S5, the transport operation of the robot arm 21 is controlled to sequentially place the substrate 10 onto each of the mounts 51 and 52, which are the mounts 50 of each of the plurality of processing modules 103, based on the acquired amount of deviation. Specifically, based on the amount of deviation of the substrate 10a, which is the substrate 10 held by the holder 23a of the substrate holding hand 23, the substrate 10a is placed onto the mount 51 having a relatively high placement position. Thereafter, based on the amount of deviation of the substrate 10b, which is the substrate 10 held by the holder 23b of the substrate holding hand 23, the substrate 10b is placed onto the mount 52 having a relatively low placement position.

Next, in step S6, the substrate holding hand 23 is moved backward from the mounts 50 of the processing module 103.

Next, in step S7, after the process on the substrates 10 is completed in the processing module 103, the substrates 10 placed one by one on each of the mounts 51 and 52, which are the mounts 50 of the processing module 103, are held by the holders 23a and 23b of the substrate holding hand 23, respectively.

Next, in step S8, the operation of the robot arm 21 is controlled to move the substrate holding hand 23 toward the load lock 102.

Next, in step S9, the detectors 60 arranged on the load lock 102 side detect the pair of substrates 10 held by the holders 23a and 23b of the substrate holding hand 23, respectively, such that the detection results from the detectors 60 are acquired.

Next, in step S10, similarly to step S4, the amount of deviation of the placement of each of the pair of substrates 10 with respect to the substrate holding hand 23 is acquired based on the detection results acquired from the detectors 60.

Next, in step S11, based on the acquired amount of deviation, the transport operation of the robot arm 21 is controlled to place each of the substrates 10 substantially simultaneously onto each of the mounts 41 and 42, which are the mounts 40 of the load lock 102. Specifically, based on the average value of the amounts of deviation of the pair of substrates 10 held by the substrate holding hand 23, the pair of substrates 10 are placed substantially simultaneously onto the mounts 41 and 42.

Next, in step S12, the substrate holding hand 23 is moved backward from the mounts 40 of the load lock 102.

In step S1 to step S12, an example in which the robot arm 21 including the substrate holding hand 23 attached thereto is operated has been described, but the same applies to a case in which the robot arm 22 including the substrate holding hand 24 attached thereto is operated. Alternatively, a step of transporting the pair of substrates 10 to the processing module 103 from step S1 to step S6 may be performed for each of the processing modules 103 such that the step may be performed a number of times that is equal to the number of processing modules 103, and then a step of transporting the pair of substrates 10 to the load lock 102 from step S7 to step S12 may be repeated the same number of times as the number of processing modules 103. In such a case, the robot arm 21 including the substrate holding hand 23 attached thereto and the robot arm 22 including the substrate holding hand 24 attached thereto may be operated alternately.

### Advantages of Embodiment

According to this embodiment, the following advantages are achieved.

The substrate transport robot system 100 includes the controller 30 configured or programmed to acquire the amount of deviation of the placement of each of the plurality of substrates 10 with respect to the predetermined reference position based on the detection results of the detectors 60 operable to detect each of the plurality of substrates 10 held by the substrate holding hands 23 and 24, and control the transport operations of the robot arms 21 and 22 operable to transport the plurality of substrates 10 based on the acquired amount of deviation such that each of the plurality of substrates 10 is loaded separately into each of the mounts 40 or the mounts 50. Accordingly, even when the substrates 10 are deviated from the predetermined reference position, the controller 30 controls the transport operations of the robot arms 21 and 22 based on the amount of deviation such that each of the plurality of substrates 10 can be transported so as to correct the placement deviation without changing the relative placement of each of the plurality of substrates 10 with respect to the substrate holding hands 23 and 24. Consequently, the plurality of substrates 10 can be accurately transported while contact with a member other than the substrates 10 is reduced or prevented.

Each of the plurality of substrates 10 is held by the substrate holding hand 23 including the plurality of holders 23a and 23b integral and unitary with each other and the substrate holding hand 24 including the plurality of holders 24a and 24b integral and unitary with each other, while being aligned right and left along the horizontal plane, and the controller 30 is configured or programmed to control the transport operations of the robot arms 21 and 22 based on the acquired amount of deviation such that each of the plurality of substrates 10 held by the plurality of holders 23a and 23b being integral and unitary with each other in the substrate holding hand 23 is loaded separately into the mounts 40 or the mounts 50, and such that each of the plurality of substrates 10 held by the plurality of holders 24a and 24b being integral and unitary with each other in the substrate holding hand 24 is loaded separately into the mounts 40 or the mounts 50. Accordingly, the transport operations of the robot arms 21 and 22 can be controlled based on the amount of deviation of each of the substrates 10 even when the substrates 10 are held by the plurality of holders 23a and 23b being integral and unitary with each other in the substrate holding hand 23 and even when the substrates 10 are held by the plurality of holders 24a and 24b being integral and unitary with each other in the substrate holding hand 24. Therefore, even when the plurality of substrates 10 are held by the integrated holders 23a and 23b and the integrated holders 24a and 24b such that the relative positional relationship between the substrates 10 is not changed, each of the plurality of substrates 10 can be placed accurately on the mounts 40 and 50 without changing the placement 4 each of the plurality of substrates 10 with respect to the substrate holding hands 23 and 24. Consequently, even when in the substrate holding hands 23 and 24 that transport the plurality of substrates 10 together, the holders 23a and 23b are integral and unitary with each other and the holders 24a and 24b are integral and unitary with each other such that the plurality of substrates 10 held therein do not move relative to each other, the plurality of substrates 10 can be accurately transported while contact with the member other than the substrates 10 is reduced or prevented.

The controller 30 is configured or programmed to sequentially place each of the plurality of substrates 10 onto each of the plurality of mounts 51 and 52 based on the amount of deviation of each of the plurality of substrates 10 when each of the plurality of substrates 10 is loaded separately into each of the plurality of mounts 51 and 52 having different placement position heights during the transport operations of the robot arms 21 and 22. Accordingly, the substrates 10 are sequentially placed onto the plurality of mounts 51 and 52 having different placement position heights such that the substrates 10 can be placed one by one while being aligned sequentially with each of the plurality of mounts 51 and 52 based on the acquired amount of deviation. Therefore, even when the amounts of deviation of the plurality of substrates 10 are different from each other, the substrates 10 can be sequentially placed onto the mounts 51 and 52 in a manner that corresponds to the amount of deviation of each of the plurality of substrates 10, and thus when the plurality of substrates 10 are transported, the substrates 10 can be more accurately transported while contact with the member other than the substrates 10 is reduced or prevented.

The substrate holding hand 23 includes the pair of holders 23a and 23b to hold the pair of substrates 10, respectively, and the substrate holding hand 24 includes the pair of holders 24a and 24b to hold the pair of substrates 10, respectively. The mounts 50 include the mount 51 to allow the substrate 10a, which is one of the pair of substrates 10, to be placed thereon, and the mount 52 being separate from the mount 51 to allow the substrate 10b, which is the other of the pair of substrates 10, to be placed thereon, and having a placement position lower than the placement position of the mount 51. The controller 30 is configured or programmed to acquire the amount of deviation of each of the substrates 10a and 10b based on the detection results of the detectors 60, and control the transport operations of the robot arms 21 and 22 such that the substrate 10a is placed onto the mount 51 based on the amount of deviation of the substrate 10a, and the substrate 10b is placed onto the mount 52 based on the amount of deviation of the substrate 10b after the substrate 10a is placed on the mount 51, when each of the plurality of substrates 10 is loaded separately into each of the mounts 51 and 52. Accordingly, the transport operations of the robot arms 21 and 22 are performed such that the substrate 10a is placed onto the mount 51 having a higher placement position of the mounts 51 and 52 that have different heights, and then the substrate 10 is placed onto the mount 52 having a lower placement position, and thus the substrates 10a and 10b can be transported in the order from the mount having a higher placement position. Therefore, in a series of operations in which the substrate holding hands 23 and 24 are moved vertically from top to bottom, the robot arms 21 and 22 can perform transport operations such that the substrates 10a and 10b are placed sequentially onto the mounts 51 and 52. Consequently, when the substrates 10a and 10b are placed onto the mounts 51 and 52, which are different in height, respectively, the complexity of the transport operations of the robot arms 21 and 22 can be reduced or prevented, and thus the plurality of substrates 10a and 10b can be transported accurately and easily while contact with the member other than the substrates 10 is reduced or prevented.

The controller 30 is configured or programmed to place each of the plurality of substrates 10 substantially simultaneously onto each of the plurality of mounts 41 and 42 based on the amount of deviation of each of the plurality of substrates 10 when each of the plurality of substrates 10 is loaded separately into each of the plurality of mounts 41 and 42 having substantially equal placement position heights during the transport operations of the robot arms 21 and 22. Accordingly, when the substrates 10 are loaded into the plurality of mounts 41 and 42 having substantially equal placement position heights, the plurality of substrates 10 can be simultaneously placed onto the plurality of mounts 41 and 42 while the positions are adjusted based on the amounts of deviation. Therefore, when the heights of the placement positions of the plurality of mounts 41 and 42 are substantially equal to each other, the substrates 10 can be placed onto the mounts 41 and 42 without performing multiple back and forth movements as compared with a case in which the substrates 10 are placed one by one sequentially. Consequently, the complexity of the transport operations of the substrate holding hands 23 and 24 can be reduced or prevented, and thus the plurality of substrates 10 can be transported accurately and easily while contact with the member other than the substrates 10 is reduced or prevented.

The controller 30 is configured or programmed to control the transport operations of the robot arms 21 and 22 based on the average value of the amounts of deviation of the plurality of substrates 10 such that each of the plurality of substrates 10 is placed substantially simultaneously onto each of the plurality of mounts 41 and 42. Accordingly, when each of the substrates 10 is placed onto each of the plurality of mounts 41 and 42 having substantially equal placement position heights, the transport operations of the robot arms 21 and 22 is controlled based on the average value of the amounts of deviation such that the plurality of substrates 10 can be transported so as to correct the amount of deviation of each of the plurality of substrates 10 on average. Therefore, each of the plurality of substrates 10 can be more accurately transported to each of the plurality of mounts 41 and 42 while contact with the member other than the substrates 10 is reduced or prevented.

The controller 30 is configured or programmed to acquire the amount of deviation of each of the plurality of substrates 10 based on the detection results of the detectors 60 after each of the plurality of substrates 10 is held by the substrate holding hands 23 and 24 when each of the plurality of substrates 10 is loaded separately into the mounts 40 and 50, and control the transport operations of the robot arms 21 and 22 based on the amount of deviation of each of the plurality of substrates 10 acquired after each of the plurality of substrates 10 is held by the substrate holding hands 23 and 24 such that each of the plurality of substrates 10 is placed separately onto the mounts 40 or the mounts 50. Accordingly, the amount of deviation of each of the plurality of substrates 10 is acquired based on the detection results of the detectors 60 after the plurality of substrates 10 are held by the substrate holding hands 23 and 24, and thus even when deviation occurs in the substrates 10 when the substrates 10 are held by the substrate holding hands 23 and 24, the transport operations of the robot arms 21 and 22 can be controlled to compensate for the amount of deviation that occurs when the substrates 10 are held by the substrate holding hands 23 and 24. Consequently, even when deviation occurs in the substrates 10 when the substrates 10 are held by the substrate holding hands 23 and 24, the substrates 10 can be accurately transported to the mounts 40 and 50 while contact with the member other than the substrates 10 is reduced or prevented.

The controller 30 is configured or programmed to acquire the amount of deviation of the placement of each of the plurality of substrates 10 with respect to the substrate holding hands 23 and 24 based on the detection results of the detectors 60 when each of the plurality of substrates 10 is loaded separately into the mounts 40 and 50. Accordingly, the transport operations of the robot arms 21 and 22 including the substrate holding hands 23 and 24 attached thereto can be controlled based on the amount of deviation of each of the substrates 10 with respect to the substrate holding hands 23 and 24. Therefore, the transport operations of the robot arms 21 and 22 are controlled such that the substrates 10 can be transported while the positions of the substrate holding hands 23 and 24 are corrected such that the substrates 10 held by the substrate holding hands 23 and 24 are placed on the mounts 40 and 50. Consequently, each of the plurality of substrates 10 can be more accurately transported to the mounts 40 and 50 while contact with the member other than the substrates 10 is reduced or prevented.

The substrate transport robot system 100 includes the robot arms 21 and 22 including the substrate holding hands 23 and 24 attached thereto, respectively, and operable separately. The detectors 60 detect each of the plurality of substrates 10 for each of the robot arms 21 and 22. The controller 30 is configured or programmed to acquire the amount of deviation of each of the plurality of substrates 10 for each of the robot arms 21 and 22 based on the detection results of the detectors 60, and control the transport operations of the robot arms 21 and 22 based on the amount of deviation of each of the plurality of substrates 10 acquired for each of the robot arms 21 and 22 such that each of the plurality of substrates 10 is loaded separately into the mounts 40 or the mounts 50. Accordingly, the transport operations of the robot arms 21 and 22 are controlled based on the amount of deviation for each of the robot arms 21 and 22 such that the plurality of substrates 10 held by the substrate holding hands 23 and 24 attached to the robot arms 21 and 22, respectively, can be accurately transported while contact with the member other than the substrates 10 is reduced or prevented for each of the robot arms 21 and 22. Consequently, the two robot arms 21 and 22 are used, and thus the number of substrates 10 transported per hour can be increased as compared with a case in which one robot arm is used to transport the substrates 10. Therefore, when a plurality of substrates 10 are transported, the substrates 10 can be accurately transported while contact with the member other than the substrates 10 is reduced or prevented, and the number of substrates transported per hour can be increased.

### Modified Examples

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which the controller 30 acquires the amount of deviation of each of the plurality of substrates 10 when each of the plurality of substrates 10 is loaded separately into the mounts 40 and 50, and controls the transport operations of the robot arms 21 and 22 based on the acquired amount of deviation has been shown in the aforementioned embodiment, the present disclosure is not limited to this. In the present disclosure, the controller may acquire the amount of deviation for each robot arm, as in the case of loading in the above embodiment, when each of the plurality of substrates is unloaded separately from the mounts, and control the transport operation of the robot arm based on the acquired amount of deviation. Accordingly, similarly to the case of loading, the plurality of substrates can be accurately transported while contact with the member other than the substrates is reduced or prevented. In such a case, the positions of the substrates placed on the mounts may be detected by a detector such as an imager, and the amount of deviation of each of the plurality of substrates placed on the mounts may be acquired with the positions of the mounts as predetermined reference positions.

Furthermore, when each of the plurality of substrates is unloaded separately from each of the plurality of mounts having different placement position heights, similarly to the case of loading, each of the plurality of substrates may be sequentially held from each of the plurality of mounts based on the amount of deviation of each of the plurality of substrates. For example, when each of a pair of first and second substrates is unloaded separately from each of a first mount and a second mount, the second substrate may be held from the second mount based on the amount of deviation of the second substrate, and after the second substrate is held from the second mount, the first substrate may be held from the first mount based on the amount of deviation of the first substrate. That is, the plurality of substrates may be held in the order from the mount that is lower in height among the plurality of mounts based on the amount of deviation. Accordingly, similarly to the case of loading, the complexity of the transport operations of the robot arms can be reduced or prevented, and thus the plurality of substrates can be transported accurately and easily while contact with the member other than the substrates is reduced or prevented.

Even when each of the plurality of substrates is unloaded separately from each of the plurality of mounts having substantially equal placement position heights, similarly to the case of loading, each of the plurality of substrates may be held substantially simultaneously based on the average value of the amounts of deviation. Accordingly, similarly to the case of loading, each of the plurality of substrates can be transported more accurately to each of the plurality of mounts while contact with the member other than the substrates is reduced or prevented. Alternatively, the amount of deviation may be acquired in the case of both loading and transport of the substrates, and the transport operations of the robot arms may be controlled based on the acquired amount of deviation.

While the example in which in the substrate holding hands 23 and 24, the plurality of substrates 10 are aligned in a right-left direction along the horizontal plane has been shown in the aforementioned embodiment, the present disclosure is not limited to this. In the present disclosure, in the substrate holding hands, the plurality of substrates may be aligned right and left, not along the horizontal plane, but offset in the vertical direction. Alternatively, the substrate holding hands may hold the substrates aligned vertically, rather than aligned right and left.

While the example in which each of the substrate holding hands 23 and 24 holds a pair of substrates 10 has been shown in the aforementioned embodiment, the present disclosure is not limited to this. In the present disclosure, the substrate holding hands may be configured to hold three or more substrates. The shapes of the holders of the substrate holding hands may not have a U-shape with a bifurcated distal end. Furthermore, the substrate holding hands may not be passive-type end effectors.

While the example in which the amount of deviation of the placement of each of the substrates 10 with respect to the substrate holding hand 23 is acquired as the amount of deviation of each of the substrates 10 with respect to the predetermined reference position based on the detection results of the detectors 60 has been shown in the aforementioned embodiment, the present disclosure is not limited to this. In the present disclosure, as the amount of deviation of each of the substrates 10 with respect to the predetermined reference position, the amount of deviation from a preset coordinate position may be acquired, or the amount of deviation with respect to the mount, which is the transport destination, may be acquired.

While the example in which the substrate transport robot system 100 includes the two robot arms 21 and 22 that operate independently of each other has been shown in the aforementioned embodiment, the present disclosure is not limited to this. In the present disclosure, the substrate transport robot system may include only one robot arm, or may include three or more robot arms. Alternatively, the two robot arms may share a portion of the arms. In other words, each of the two robot arms may be connected to a common member that rotates with respect to the base.

While the example in which the detectors 60 that detect the substrates 10 are transmissive laser sensors has been shown in the aforementioned embodiment, the present disclosure is not limited to this. In the present disclosure, the detectors may be reflective laser sensors or imagers such as cameras that capture external images. That is, the amount of deviation of each of the substrates may be acquired based on the captured external images. Alternatively, the detectors may be arranged on the transport robot of the substrate transport robot system. For example, the detectors may be arranged on the base to which the robot arms are connected. Alternatively, the detectors may be arranged on the robot arms or the substrate holding hands.

While the example in which when the substrates 10 are sequentially placed onto the mounts 51 and 52 having different placement position heights, the detectors 60 detect each of the pair of substrates 10 during movement of the substrates toward the mounts 51 and 52 such that the amounts of deviation of both of the pair of substrates 10 held by the substrate holding hands 23 and 24 are acquired has been shown in the aforementioned embodiment, the present disclosure is not limited to this. In the present disclosure, the amount of deviation of the substrate to be placed on the mount with the lower placement position may be acquired by detecting the substrate after the substrate is placed on the mount with the higher placement position and before the substrate is placed on the mount with the lower placement position.

While the example in which each of the plurality of processing modules 103 includes two mounts 50, i.e., the mount 51 and the mount 52 having different placement position heights, has been shown in the aforementioned embodiment, the present disclosure is not limited to this. In the present disclosure, some or all of the processing modules may include a plurality of mounts having substantially equal placement position heights. Alternatively, each of the plurality of mounts may include a drive mechanism to change the placement position height thereof. In such a case, when each of the plurality of substrates is to be placed, the position of the substrate holding hand is adjusted based on the amount of deviation, and the heights of the mounts are changed such that each of the plurality of substrates is placed onto each of the mounts. Specifically, the transport operation of the robot arm may be controlled such that the substrates held by the substrate holding hand are arranged directly above the mounts, and the substrates may be loaded by moving the mounts upward.

While the example in which the substrate transport robot system 100 transports the substrates 10 in the transport chamber 104 maintained at the predetermined vacuum level has been shown in the aforementioned embodiment, the present disclosure is not limited to this. In the present disclosure, the substrates may be transported at normal pressure.

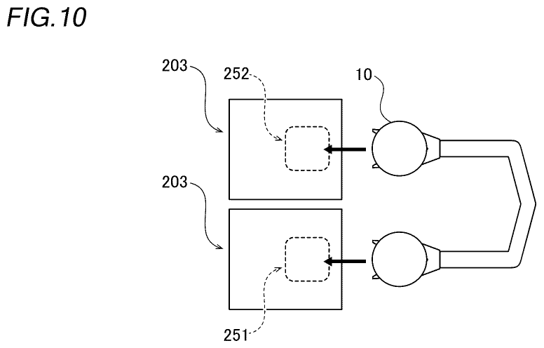

As in a substrate processing system according to a modified example shown in FIG. 10, processing modules 203 that each process one substrate 10 may be arranged in pairs adjacent to each other. In such a case, respective mounts 251 and 252 of a pair of adjacent processing modules 203 may have different placement position heights. That is, the placement position of the mount 251 of one of the pair of adjacent processing modules 203 may be higher than the placement position of the mount 252 of the other of the pair of adjacent processing modules 203. In such a case, similarly to the above embodiment, the transport operations may be controlled such that the substrate 10 is placed on the mount 251 based on the amount of deviation of one substrate 10, and then the substrate 10 is placed on the mount 252 based on the amount of deviation of the other substrate 10. The mounts 251 and 252 are examples of a first mount and a second mount, respectively.

The functionality of the elements disclosed herein may be implemented using circuitry or processing circuitry that includes general purpose processors, special purpose processors, integrated circuits, application specific integrated circuits (ASICs), conventional circuitry and/or combinations thereof that are configured or programmed to perform the disclosed functionality. Processors are considered processing circuitry or circuitry as they include transistors and other circuitry therein. In the present disclosure, the circuitry, units, or means are hardware that carries out the recited functionality or hardware that is programmed to perform the recited functionality. The hardware may be hardware disclosed herein or other known hardware that is programmed or configured to carry out the recited functionality. When the hardware is a processor that may be considered a type of circuitry, the circuitry, means, or units are a combination of hardware and software, and the software is used to configure the hardware and/or processor.

### Aspects

It will be appreciated by those skilled in the art that the exemplary embodiments described above are specific examples of the following aspects.
(Item 1)

A substrate transport robot system comprising:
a substrate holding hand including a plurality of holders to hold a plurality of substrates, respectively;
a robot arm including the substrate holding hand attached thereto; and
a controller configured or programmed to acquire an amount of deviation of placement of each of the plurality of substrates with respect to a predetermined reference position based on a detection result of a detector operable to detect each of the plurality of substrates held by the substrate holding hand, and control a transport operation of the robot arm operable to transport the plurality of substrates based on an acquired amount of deviation such that each of the plurality of substrates is loaded separately into a mount and/or unloaded separately from the mount.
(Item 2)

The substrate transport robot system according to item 1, wherein
each of the plurality of substrates is held by the substrate holding hand including the plurality of holders integral and unitary with each other, while being aligned right and left along a horizontal plane; and
the controller is configured or programmed to control the transport operation of the robot arm based on the acquired amount of deviation such that each of the plurality of substrates held by the plurality of holders being integral and unitary with each other in the substrate holding hand is loaded separately into the mount and/or unloaded separately from the mount.
(Item 3)

The substrate transport robot system according to item 1 or 2, wherein the controller is configured or programmed to, during the transport operation of the robot arm, sequentially place each of the plurality of substrates onto each of a plurality of the mounts having different placement position heights based on the amount of deviation of each of the plurality of substrates when each of the plurality of substrates is loaded separately into each of the plurality of mounts, and/or sequentially hold each of the plurality of substrates from each of the plurality of mounts based on the amount of deviation of each of the plurality of substrates when each of the plurality of substrates is unloaded separately from each of the plurality of mounts.
(Item 4)

The substrate transport robot system according to item 3, wherein
the substrate holding hand includes a pair of the holders to hold a pair of the substrates, respectively;
the plurality of mounts include a first mount to allow a first substrate, which is one of the pair of substrates, to be placed thereon, and a second mount being separate from the first mount to allow a second substrate, which is the other of the pair of substrates, to be placed thereon, the second mount having a placement position lower than a placement position of the first mount; and
the controller is configured or programmed to:
   acquire the amount of deviation of each of the first substrate and the second substrate based on the detection result of the detector;
   control the transport operation of the robot arm such that the first substrate is placed onto the first mount based on the amount of deviation of the first substrate, and the second substrate is placed onto the second mount based on the amount of deviation of the second substrate after the first substrate is placed on the first mount, when each of the plurality of substrates is loaded separately into each of the first mount and the second mount; and
   control the transport operation of the robot arm such that the second substrate is held from the second mount based on the amount of deviation of the second substrate, and the first substrate is held from the first mount based on the amount of deviation of the first substrate after the second substrate is held from the second mount, when each of the plurality of substrates is unloaded separately from each of the first mount and the second mount.
(Item 5)

The substrate transport robot system according to any one of items 1 to 4, wherein the controller is configured or programmed to, during the transport operation of the robot arm, place each of the plurality of substrates substantially simultaneously onto each of a plurality of the mounts having substantially equal placement position heights based on the amount of deviation of each of the plurality of substrates when each of the plurality of substrates is loaded separately into each of the plurality of mounts, and/or hold each of the plurality of substrates substantially simultaneously from each of the plurality of mounts based on the amount of deviation of each of the plurality of substrates when each of the plurality of substrates is unloaded separately from each of the plurality of mounts.
(Item 6)

The substrate transport robot system according to item 5, wherein the controller is configured or programmed to control the transport operation of the robot arm based on an average value of amounts of deviation of the plurality of substrates such that each of the plurality of substrates is placed substantially simultaneously onto each of the plurality of mounts and/or held substantially simultaneously from each of the plurality of mounts.
(Item 7)

The substrate transport robot system according to any one of items 1 to 6, wherein the controller is configured or programmed to:
acquire the amount of deviation of each of the plurality of substrates based on the detection result of the detector after each of the plurality of substrates is held by the substrate holding hand when each of the plurality of substrates is loaded separately into the mount; and
control the transport operation of the robot arm based on the amount of deviation of each of the plurality of substrates acquired after each of the plurality of substrates is held by the substrate holding hand such that each of the plurality of substrates is placed separately onto the mount.
(Item 8)

The substrate transport robot system according to any one of items 1 to 7, wherein the controller is configured or programmed to:
acquire the amount of deviation of the placement of each of the plurality of substrates with respect to the substrate holding hand based on the detection result of the detector when each of the plurality of substrates is loaded separately into the mount; and
acquire the amount of deviation of the placement of each of the plurality of substrates with respect to the mount based on the detection result of the detector when each of the plurality of substrates is unloaded separately from the mount.
(Item 9)

The substrate transport robot system according to any one of items 1 to 8, wherein
the robot arm includes a first robot arm and a second robot arm each including the substrate holding hand attached thereto, the first robot arm and the second robot arm being operable separately;
the detector is operable to detect each of the plurality of substrates for each of the first robot arm and the second robot arm; and
the controller is configured or programmed to:
   acquire the amount of deviation of each of the plurality of substrates for each of the first robot arm and the second robot arm based on the detection result of the detector; and
   control the transport operation of the robot arm based on the amount of deviation of each of the plurality of substrates acquired for each of the first robot arm and the second robot arm such that each of the plurality of substrates is loaded separately into the mount and/or unloaded separately from the mount.

1. A substrate transport robot system comprising:
a substrate holding hand including a plurality of holders to hold a plurality of substrates, respectively;
a robot arm including the substrate holding hand attached thereto; and
a controller configured or programmed to acquire an amount of deviation of placement of each of the plurality of substrates with respect to a predetermined reference position based on a detection result of a detector operable to detect each of the plurality of substrates held by the substrate holding hand, and control a transport operation of the robot arm operable to transport the plurality of substrates based on an acquired amount of deviation such that each of the plurality of substrates is loaded separately into a mount and/or unloaded separately from the mount.

2. The substrate transport robot system according to claim 1, wherein
each of the plurality of substrates is held by the substrate holding hand including the plurality of holders integral and unitary with each other, while being aligned right and left along a horizontal plane; and
the controller is configured or programmed to control the transport operation of the robot arm based on the acquired amount of deviation such that each of the plurality of substrates held by the plurality of holders being integral and unitary with each other in the substrate holding hand is loaded separately into the mount and/or unloaded separately from the mount.

3. The substrate transport robot system according to claim 1, wherein the controller is configured or programmed to, during the transport operation of the robot arm, sequentially place each of the plurality of substrates onto each of a plurality of the mounts having different placement position heights based on the amount of deviation of each of the plurality of substrates when each of the plurality of substrates is loaded separately into each of the plurality of mounts, and/or sequentially hold each of the plurality of substrates from each of the plurality of mounts based on the amount of deviation of each of the plurality of substrates when each of the plurality of substrates is unloaded separately from each of the plurality of mounts.

4. The substrate transport robot system according to claim 3, wherein
the substrate holding hand includes a pair of the holders to hold a pair of the substrates, respectively;
the plurality of mounts include a first mount to allow a first substrate, which is one of the pair of substrates, to be placed thereon, and a second mount being separate from the first mount to allow a second substrate, which is the other of the pair of substrates, to be placed thereon, the second mount having a placement position lower than a placement position of the first mount; and
the controller is configured or programmed to:
acquire the amount of deviation of each of the first substrate and the second substrate based on the detection result of the detector;
control the transport operation of the robot arm such that the first substrate is placed onto the first mount based on the amount of deviation of the first substrate, and the second substrate is placed onto the second mount based on the amount of deviation of the second substrate after the first substrate is placed on the first mount, when each of the plurality of substrates is loaded separately into each of the first mount and the second mount; and
control the transport operation of the robot arm such that the second substrate is held from the second mount based on the amount of deviation of the second substrate, and the first substrate is held from the first mount based on the amount of deviation of the first substrate after the second substrate is held from the second mount, when each of the plurality of substrates is unloaded separately from each of the first mount and the second mount.

5. The substrate transport robot system according to claim 1, wherein the controller is configured or programmed to, during the transport operation of the robot arm, place each of the plurality of substrates substantially simultaneously onto each of a plurality of the mounts having substantially equal placement position heights based on the amount of deviation of each of the plurality of substrates when each of the plurality of substrates is loaded separately into each of the plurality of mounts, and/or hold each of the plurality of substrates substantially simultaneously from each of the plurality of mounts based on the amount of deviation of each of the plurality of substrates when each of the plurality of substrates is unloaded separately from each of the plurality of mounts.

6. The substrate transport robot system according to claim 5, wherein the controller is configured or programmed to control the transport operation of the robot arm based on an average value of amounts of deviation of the plurality of substrates such that each of the plurality of substrates is placed substantially simultaneously onto each of the plurality of mounts and/or held substantially simultaneously from each of the plurality of mounts.

7. The substrate transport robot system according to claim 1, wherein the controller is configured or programmed to:
acquire the amount of deviation of each of the plurality of substrates based on the detection result of the detector after each of the plurality of substrates is held by the substrate holding hand when each of the plurality of substrates is loaded separately into the mount; and
control the transport operation of the robot arm based on the amount of deviation of each of the plurality of substrates acquired after each of the plurality of substrates is held by the substrate holding hand such that each of the plurality of substrates is placed separately onto the mount.

8. The substrate transport robot system according to claim 1, wherein the controller is configured or programmed to:
acquire the amount of deviation of the placement of each of the plurality of substrates with respect to the substrate holding hand based on the detection result of the detector when each of the plurality of substrates is loaded separately into the mount; and
acquire the amount of deviation of the placement of each of the plurality of substrates with respect to the mount based on the detection result of the detector when each of the plurality of substrates is unloaded separately from the mount.

9. The substrate transport robot system according to claim 1, wherein
the robot arm includes a first robot arm and a second robot arm each including the substrate holding hand attached thereto, the first robot arm and the second robot arm being operable separately;
the detector is operable to detect each of the plurality of substrates for each of the first robot arm and the second robot arm; and
the controller is configured or programmed to:
acquire the amount of deviation of each of the plurality of substrates for each of the first robot arm and the second robot arm based on the detection result of the detector; and
control the transport operation of the robot arm based on the amount of deviation of each of the plurality of substrates acquired for each of the first robot arm and the second robot arm such that each of the plurality of substrates is loaded separately into the mount and/or unloaded separately from the mount.
